(19) United States
(12) Patent Application Publication
(10) Pub. No.: US 2026/0344384 A1
(43) Pub. Date: Oct. 29, 2026

(54) SEMICONDUCTOR DEVICE STRUCTURE WITH CONDUCTIVE PLUG AND METHOD FOR FORMING THE SAME

(71) Applicant: Taiwan Semiconductor Manufacturing Company, Ltd., Hsinchu (TW)

(72) Inventors: Keng-Ying LIAO, Tainan City (TW); Chen-Chi HSIAO, Taipei City (TW); Chih-Wei SUNG, Kaohsiung City (TW)

(73) Assignee: Taiwan Semiconductor Manufacturing Company, Ltd., Hsinchu (TW)

(21) Appl. No.: 19/189,757

(22) Filed: Apr. 25, 2025

(51) Int. Cl. H10W 20/00; H10W 20/20

(52) U.S. Cl. CPC H10W 20/023; H10W 20/20

(57) ABSTRACT

A method for forming a semiconductor device structure is provided. The method includes providing a substrate including a first semiconductive layer, a second semiconductive layer, an oxide layer, and an isolation structure. The method includes partially removing the isolation structure and the second semiconductive layer to form a hole passing through the isolation structure and the second semiconductive layer. The method includes forming a spacer layer over an inner wall of the hole. The method includes removing a portion of the oxide layer under the hole. The method includes forming a conductive plug in the hole. The conductive plug passes through the isolation structure, the second semiconductive layer, the spacer layer, and the oxide layer and is electrically connected to the first semiconductive layer, and the conductive plug includes a metal-containing material.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1P are cross-sectional views of various stages of a process for forming a semiconductor device structure, in accordance with some embodiments.

FIG. 2 is a cross-sectional view of a semiconductor device structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as "substantially parallel" or "substantially perpendicular" may be interpreted as not to exclude insignificant deviation from the specified arrangement and may include for example deviations of up to 10°. The word "substantially" does not exclude "completely" e.g. a composition which is "substantially free" from Y may be completely free from Y.

The term "about" may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term "about" in relation to a numerical value x may mean x ±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order. Source/drain structure(s) may refer to a source or a drain, individually or collectively dependent upon the context.

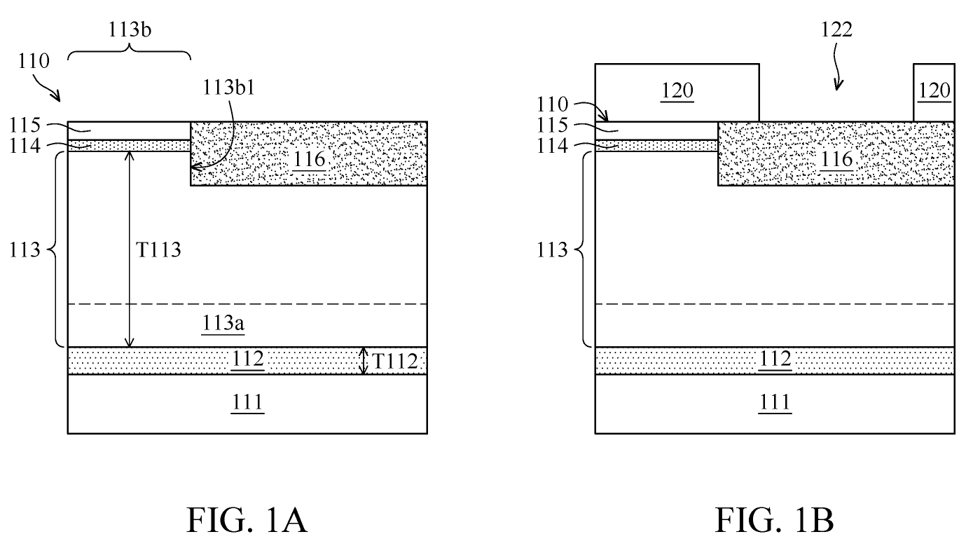

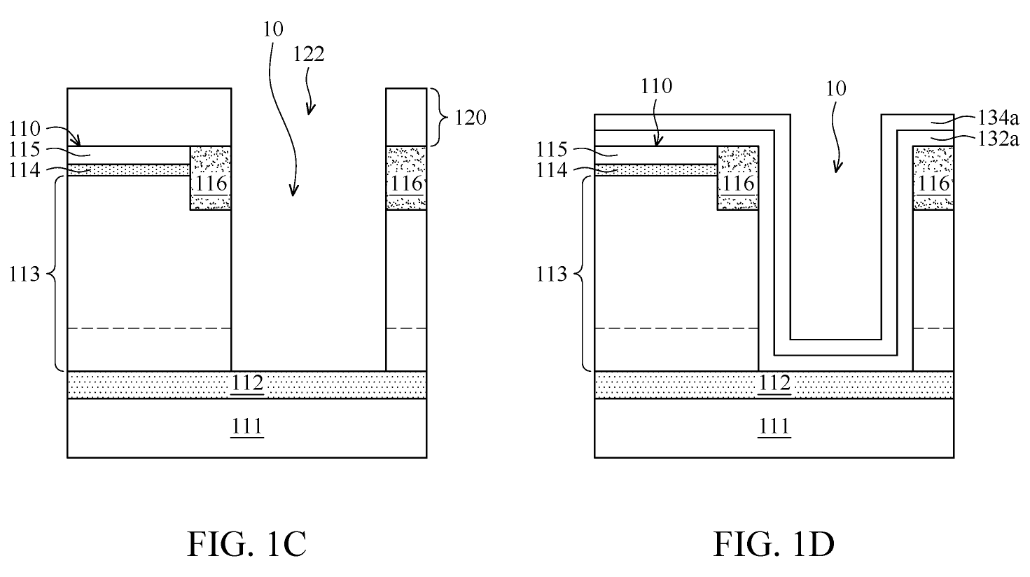

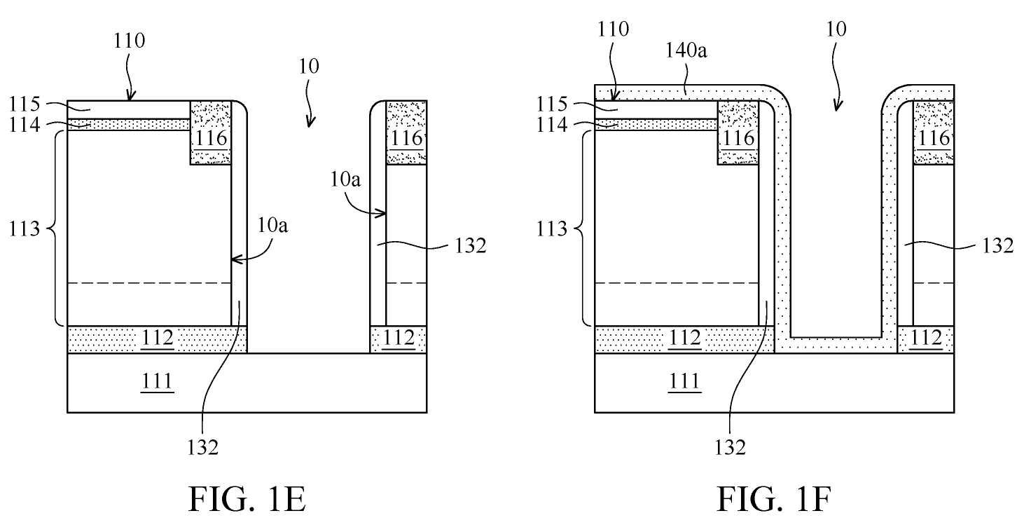

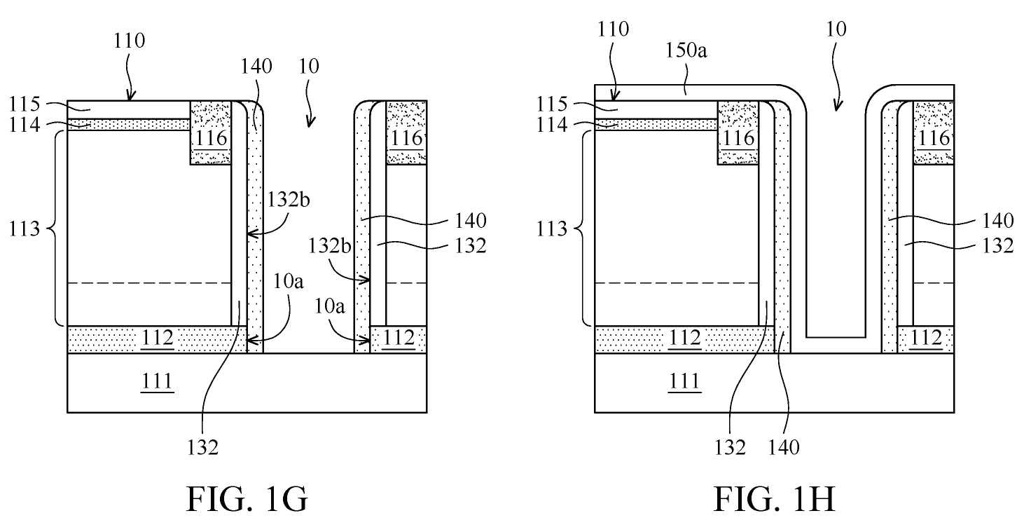

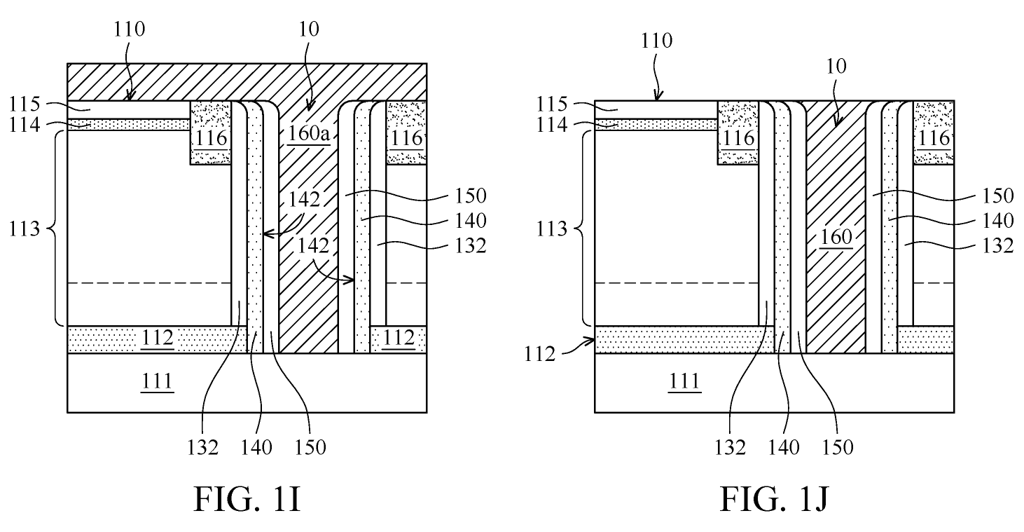

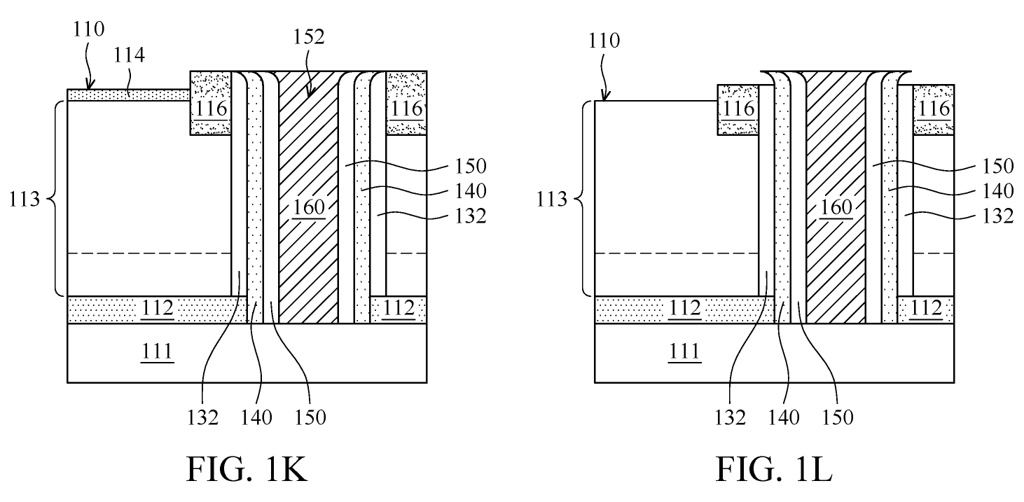

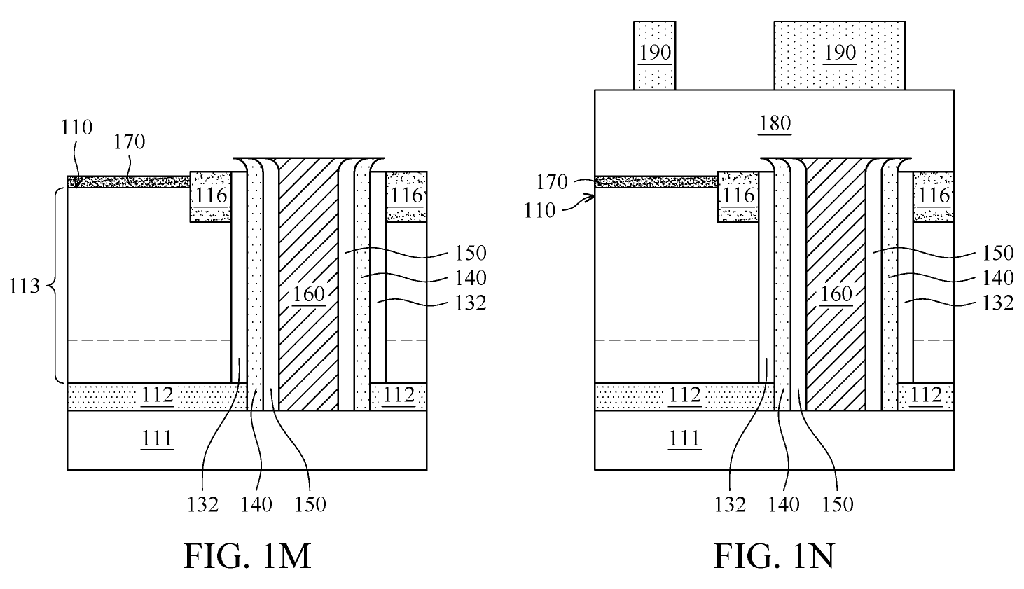

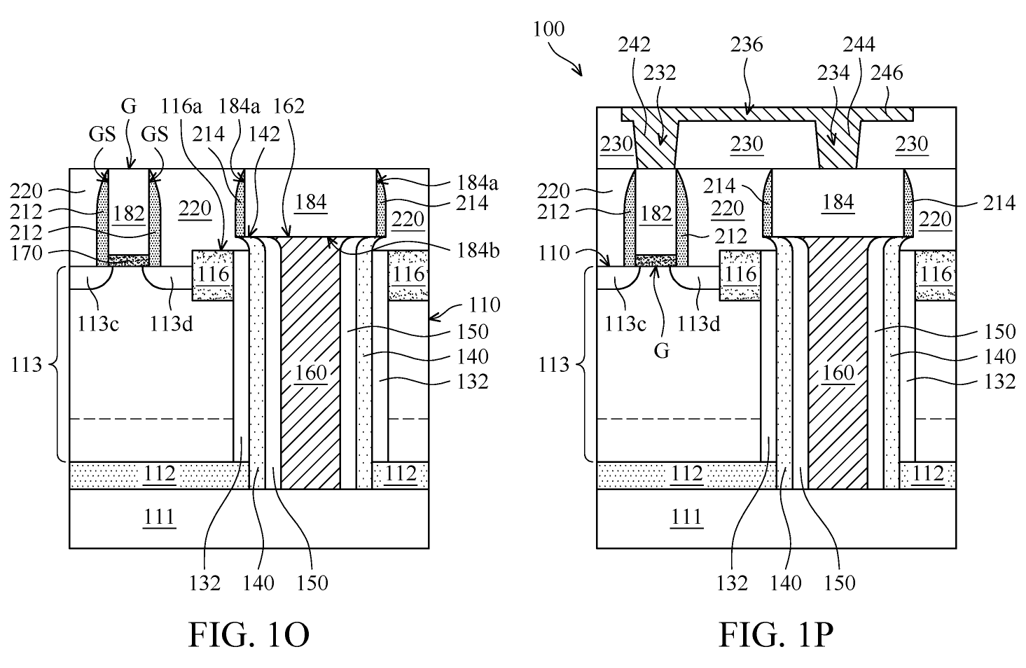

FIGS. 1A-1R are cross-sectional views of various stages of a process for forming a semiconductor device structure, in accordance with some embodiments. As shown in FIG. 1A, a substrate 110 is provided, in accordance with some embodiments.

The substrate 110 is also referred to as a semiconductor on insulator (SOI) substrate, in accordance with some embodiments. The substrate 110 includes a semiconductive layer 111, an oxide layer 112, a semiconductive layer 113, an oxide layer 114, a mask layer 115, and an isolation structure 116, in accordance with some embodiments.

The semiconductive layer 111 is made of an elementary semiconductor material including silicon or germanium in a single crystal structure, a polycrystal structure, or an amorphous structure. In some other embodiments, the semiconductive layer 111 is made of a compound semiconductor, such as silicon carbide, gallium arsenide, gallium phosphide, indium phosphide, indium arsenide, an alloy semiconductor, such as SiGe or GaAsP, or a combination thereof.

In some embodiments, the semiconductive layer 111 is doped with n-type dopants, in accordance with some embodiments. The n-type dopants include phosphorus or arsenic, in accordance with some embodiments. In some other embodiments, the semiconductive layer 111 is doped with p-type dopants, in accordance with some embodiments. The p-type dopants include boron or BF₂, in accordance with some embodiments.

The oxide layer 112 is formed over the semiconductive layer 111, in accordance with some embodiments. The oxide layer 112 is made of an oxide material such as silicon oxide, in accordance with some embodiments. The oxide layer 112 has a thickness T112 ranging from about 0.1 μm to about 0.5 μm, in accordance with some embodiments.

The semiconductive layer 113 is formed over the oxide layer 112, in accordance with some embodiments. The oxide layer 112 is between the semiconductive layer 111 and the semiconductive layer 113, in accordance with some embodiments. The thickness T113 of the semiconductive layer 113 ranges from about 2 μm to about 7 μm@

The semiconductive layer 113 has a doped region 113a, in accordance with some embodiments. The doped region 113a is doped with dopants, in accordance with some embodiments. The dopants include p-type dopants or n-type dopants, in accordance with some embodiments. The p-type dopants include boron or BF₂, in accordance with some embodiments. The n-type dopants include phosphorus or arsenic, in accordance with some embodiments.

The semiconductive layer 113 is made of an elementary semiconductor material including silicon or germanium in a single crystal structure, a polycrystal structure, or an amorphous structure. In some other embodiments, the semiconductive layer 113 is made of a compound semiconductor, such as silicon carbide, gallium arsenide, gallium phosphide, indium phosphide, indium arsenide, an alloy semiconductor, such as SiGe or GaAsP, or a combination thereof.

The oxide layer 114 is formed over the semiconductive layer 113, in accordance with some embodiments. The oxide layer 114 is also referred to as a native oxide layer, in accordance with some embodiments. The oxide layer 114 is made of an oxide material such as silicon oxide, in accordance with some embodiments.

The mask layer 115 is formed over the oxide layer 114, in accordance with some embodiments. The mask layer 115, the oxide layer 114, and the semiconductive layer 113 are made of different materials, in accordance with some embodiments. The mask layer 115 is made of a nitride material, in accordance with some embodiments. The nitride material includes silicon nitride, in accordance with some embodiments.

The isolation structure 116 is formed in the semiconductive layer 113, in accordance with some embodiments. The isolation structure 116 passes through the mask layer 115 and the oxide layer 114 and extends into the semiconductive layer 113, in accordance with some embodiments.

The isolation structure 116 surrounds an active region 113b of the semiconductive layer 113, in accordance with some embodiments. The isolation structure 116 interfaces an end portion 113b1 of the active region 113b, in accordance with some embodiments. The isolation structure 116 is made of an oxide-based material, in accordance with some embodiments. The oxide-based material includes silicon oxide, in accordance with some embodiments.

In some other embodiments, the isolation structure 116 is made of a low-k material or a porous dielectric material having a k-value which is lower than that of silicon oxide, or lower than about 3.0 or about 2.5, in accordance with some embodiments. The low-k material includes a fluorinated material, such as amorphous fluorinated carbon (α-C:F), poly-tetra-fluoro-ethylene (PTFE), fluorinated polyimide, or phosphor-silicate glass, in accordance with some embodiments.

Alternatively, the isolation structure 116 includes an oxide-containing material (e.g., tetraethyl orthosilicate oxide), an oxynitride-containing material (e.g., silicon oxynitride), a glass material (e.g., borosilicate glass, phosphoric silicate glass, boron phospho-silicate glass, or fluorinated silicate glass), or a combination thereof, in accordance with some embodiments.

The isolation structure 116 is formed using a deposition process and a planarization process, in accordance with some embodiments. The deposition process includes a chemical vapor deposition (CVD) process, such as a low-pressure CVD process, a plasma-enhanced CVD process, or a high-density plasma CVD process, an atomic layer deposition process, a spin-on process, a physical vapor deposition process, or another suitable process, in accordance with some embodiments.

As shown in FIG. 1B, a mask layer 120 is formed over the substrate 110, in accordance with some embodiments. The mask layer 120 has an opening 122, in accordance with some embodiments. The opening 122 passes through the mask layer 120, in accordance with some embodiments.

The opening 122 exposes a portion of the isolation structure 116, in accordance with some embodiments. The mask layer 120 is made of a polymer material such as a photoresist material, in accordance with some embodiments.

As shown in FIG. 1C, portions of the isolation structure 116 and the semiconductive layer 113 under the opening 122 of the mask layer 120 are removed to form a hole 10, in accordance with some embodiments. The hole 10 passes through the isolation structure 116 and the semiconductive layer 113, in accordance with some embodiments.

The hole 10 exposes a portion of the oxide layer 112, in accordance with some embodiments. The removal process includes an etching process, such as an anisotropic etching process (e.g., a dry etching process), in accordance with some embodiments.

As shown in FIG. 1D, the mask layer 120 is removed, in accordance with some embodiments. As shown in FIG. 1D, a spacer material layer 132a is formed over the substrate 110 and in the hole 10, in accordance with some embodiments. The spacer material layer 132a is made of insulating materials, such as silicon oxide, silicon nitride, silicon oxynitride, or silicon carbide, in accordance with some embodiments.

The spacer material layer 132a is formed using a deposition process, in accordance with some embodiments. The deposition process includes a chemical vapor deposition (CVD) process, such as a sub-atmospheric CVD (SACVD) process, a low-pressure CVD process, a plasma-enhanced CVD process, or a high-density plasma CVD process, in accordance with some embodiments.

As shown in FIG. 1D, a spacer material layer 134a is formed over the spacer material layer 132a, in accordance with some embodiments. The spacer material layer 134a is made of insulating materials, such as silicon oxide, silicon nitride, silicon oxynitride, or silicon carbide, in accordance with some embodiments.

The spacer material layer 134a is formed using a deposition process, in accordance with some embodiments. The deposition process includes a chemical vapor deposition (CVD) process, such as a Sub-Atmospheric CVD (SACVD) process, a low-pressure CVD process, a plasma-enhanced CVD process, or a high-density plasma CVD process, in accordance with some embodiments.

As shown in FIGS. 1D and 1E, the spacer material layer 134a, a bottom portion of the spacer material layer 132a, and a portion of the oxide layer 112 under the bottom portion of the spacer material layer 132a are removed, in accordance with some embodiments. The hole 10 passes through the oxide layer 112 after the portion of the oxide layer 112 is removed, in accordance with some embodiments.

The portion of the spacer material layer 132a remaining over inner walls 10a of the hole 10 form a spacer layer 132 after the removal process is performed, in accordance with some embodiments. Therefore, the spacer layer 132 covers the inner walls 10a, in accordance with some embodiments.

As shown in FIG. 1F, an insulating material layer 140a is formed over the substrate 110, the spacer layer 132, and in the hole 10, in accordance with some embodiments. The insulating material layer 140a is made of an insulating material such as a metal oxide material, in accordance with some embodiments. The metal oxide material includes aluminum oxide, in accordance with some embodiments.

The insulating material layer 140a is formed using a deposition process, in accordance with some embodiments. The deposition process includes a chemical vapor deposition (CVD) process, such as a sub-atmospheric CVD (SACVD) process, a low-pressure CVD process, a plasma-enhanced CVD process, or a high-density plasma CVD process, in accordance with some embodiments.

As shown in FIGS. 1F and 1G, portions of the insulating material layer 140a are removed, in accordance with some embodiments. The portion of the insulating material layer 140a remaining over the sidewalls 132b of the spacer layer 132 and the inner walls 10a of the hole 10 form an insulating layer 140, in accordance with some embodiments.

The removal process includes an etching process, such as an anisotropic etching process (e.g., a dry etching process), in accordance with some embodiments.

As shown in FIG. 1H, an insulating material layer 150a is formed over the substrate 110, the spacer layer 132, and the insulating layer 140, and in the hole 10, in accordance with some embodiments. The insulating material layer 150a is made of an insulating material such as a metal oxide material, in accordance with some embodiments. The metal oxide material includes hafnium oxide (HfO₂), in accordance with some embodiments.

The insulating material layer 150a is formed using a deposition process, in accordance with some embodiments. The deposition process includes a chemical vapor deposition (CVD) process, such as a sub-atmospheric CVD (SACVD) process, a low-pressure CVD process, a plasma-enhanced CVD process, or a high-density plasma CVD process, in accordance with some embodiments.

As shown in FIGS. 1H and 1I, portions of the insulating material layer 150a are removed, in accordance with some embodiments. The portion of the insulating material layer 150a remaining over the sidewalls 142 of the spacer layer 140 form an insulating layer 150, in accordance with some embodiments.

The insulating layers 140 and 150 are made of different insulating materials, in accordance with some embodiments. The dielectric constant of the insulating layer 140 is greater than the dielectric constant of the insulating layer 150, in accordance with some embodiments. The removal process includes an etching process, such as an anisotropic etching process (e.g., a dry etching process), in accordance with some embodiments.

As shown in FIG. 1I, a conductive layer 160a is formed over the substrate 110, the spacer layer 132, and the insulating layers 140 and 150, and in the hole 10, in accordance with some embodiments. The conductive layer 160a is made of a metal-containing material, in accordance with some embodiments.

The metal-containing material includes a metal oxide material, in accordance with some embodiments. The metal oxide material includes tantalum oxide, in accordance with some embodiments. In some other embodiment, the metal-containing material includes copper, tungsten, gold, silver, or alloys thereof, in accordance with some embodiments.

As shown in FIGS. 1I and 1J, portions of the conductive layer 160a outside of the hole 10 are removed, in accordance with some embodiments. The portion of the conductive layer 160a remaining in the hole 10 form a conductive plug 160, in accordance with some embodiments. The conductive plug 160 is also referred to as a ground conductive plug, in accordance with some embodiments.

The conductive plug 160 passes through the isolation structure 116, the semiconductive layer 113, the spacer layer 132, the insulating layers 140 and 150, and the oxide layer 112, in accordance with some embodiments. The conductive plug 160 is electrically connected to the semiconductive layer 111, in accordance with some embodiments.

The insulating layer 150 is between the insulating layer 140 and the conductive plug 160, in accordance with some embodiments. The spacer layer 132 is between the conductive plug 160 and the semiconductive layer 113, in accordance with some embodiments. The insulating layer 140 is between the spacer layer 132 and the conductive plug 160 and between the oxide layer 112 and the conductive plug 160, in accordance with some embodiments.

The removal process includes a planarization process, in accordance with some embodiments. The planarization process includes a chemical mechanical polishing process, in accordance with some embodiments.

As shown in FIG. 1K, the mask layer 115 is removed, in accordance with some embodiments. The removal process includes an etching process such as a wet etching process, in accordance with some embodiments. The wet etching process uses an etchant including H₃PO₄, in accordance with some embodiments.

As shown in FIG. 1L, the oxide layer 114 is removed, in accordance with some embodiments. In some embodiments, top portions of the isolation structure 116 and the spacer layer 132 are also removed.

The removal process includes an etching process such as a wet etching process, in accordance with some embodiments. The wet etching process uses an etchant including HF, in accordance with some embodiments.

As shown in FIG. 1M, a gate dielectric layer 170 is formed over the semiconductive layer 113, in accordance with some embodiments. The gate dielectric layer 170 is made of a dielectric material, in accordance with some embodiments. The dielectric material includes an oxide material such as silicon oxide, in accordance with some embodiments. The gate dielectric layer 170 is formed using an oxidation process such as a thermal oxidation process, in accordance with some embodiments.

As shown in FIG. 1N, a gate electrode material layer 180 is formed over the gate dielectric layer 170, the isolation structure 116, the spacer layer 132, the insulating layers 140 and 150, and the conductive plug 160, in accordance with some embodiments. The gate electrode material layer 180 is made of a conductive material or a semiconductor material (e.g., silicon), in accordance with some embodiments.

As shown in FIG. 1N, a mask layer 190 is formed over the gate electrode material layer 180, in accordance with some embodiments. The mask layer 190 exposes portions of the gate electrode material layer 180, in accordance with some embodiments. The mask layer 190 is made of a polymer material, in accordance with some embodiments. The polymer material includes a photoresist material, in accordance with some embodiments.

As shown in FIGS. 1N and 1O, the mask layer 190 and the portions of the gate electrode material layer 180 exposed by the mask layer 190 are removed, in accordance with some embodiments. The portions of the gate dielectric layer 170 under the removed portions of the gate electrode material layer 180 are also removed, in accordance with some embodiments.

The portion of the gate electrode material layer 180 remaining over the semiconductive layer 113 form a gate electrode 182, in accordance with some embodiments. The gate electrode 182 and the gate dielectric layer 170 thereunder together form a gate stack G, in accordance with some embodiments.

The portion of the gate electrode material layer 180 remaining over the conductive plug 160 form a dummy gate electrode 184, in accordance with some embodiments. The dummy gate electrode 184 is electrically and physically connected to the conductive plug 160, in accordance with some embodiments.

The dummy gate electrode 184 and the gate electrode 182 of the gate stack G are made of the same material, in accordance with some embodiments. The bottom surface 184b of the dummy gate electrode 184 is substantially level with the top surface 162 of the conductive plug 160, in accordance with some embodiments.

The top surface 162 of the conductive plug 160 is higher than the top surface 116a of the isolation structure 116, in accordance with some embodiments. The top surface 142 of the insulating layer 140 is higher than the top surface 116a of the isolation structure 116, in accordance with some embodiments.

As shown in FIG. 1O, a spacer layer 212 is formed over sidewalls GS of the gate stack G, and a spacer layer 214 is formed over sidewalls 184a of the dummy gate electrode 184, in accordance with some embodiments. The spacer layer 212 surrounds the gate stack G, in accordance with some embodiments. The spacer layer 214 surrounds the dummy gate electrode 184, in accordance with some embodiments.

The spacer layers 212 and 214 are made of the same dielectric material, in accordance with some embodiments. The dielectric material includes silicon oxide, silicon nitride, silicon oxynitride, or silicon carbide, in accordance with some embodiments. The formation of the spacer layers 212 and 214 includes a deposition process and an anisotropic etching process, in accordance with some embodiments.

As shown in FIG. 1O, source drain regions 113c and 113d are formed in the semiconductive layer 113, in accordance with some embodiments. The gate stack G is between the source drain regions 113c and 113d, in accordance with some embodiments.

As shown in FIG. 1O, a dielectric layer 220 is formed over the substrate 110, in accordance with some embodiments. The gate stack G, the spacer layers 212 and 214, and the dummy gate electrode 184 are embedded in the dielectric layer 220, in accordance with some embodiments.

The dielectric layer 220 includes silicon oxide, silicon oxynitride, borosilicate glass (BSG), phosphoric silicate glass (PSG), borophosphosilicate glass (BPSG), fluorinated silicate glass (FSG), low-k material, porous dielectric material, or a combination thereof, in accordance with some embodiments.

The dielectric layer 220 is formed using a deposition process or a spin-on process and a chemical mechanical polishing process and/or an etching back process, in accordance with some embodiments. The deposition process includes a chemical vapor deposition process, a high density plasma chemical vapor deposition process, a flowable chemical vapor deposition process, a sputtering process, or a combination thereof.

As shown in FIG. 1P, a dielectric layer 230 is formed over the dielectric layer 220, the gate stack G, the spacer layers 212 and 214, and the dummy gate electrode 184, in accordance with some embodiments. The dielectric layer 230 includes silicon oxide, silicon oxynitride, borosilicate glass (BSG), phosphoric silicate glass (PSG), borophosphosilicate glass (BPSG), fluorinated silicate glass (FSG), low-k material, porous dielectric material, or a combination thereof, in accordance with some embodiments.

The dielectric layer 230 is formed using a deposition process or a spin-on process and a chemical mechanical polishing process and/or an etching back process, in accordance with some embodiments. The deposition process includes a chemical vapor deposition process, a high density plasma chemical vapor deposition process, a flowable chemical vapor deposition process, a sputtering process, or a combination thereof.

As shown in FIG. 1P, portions of the dielectric layer 230 are removed to form holes 232 and 234 and a trench 236, in accordance with some embodiments. The trench 236 connects the holes 232 and 234, in accordance with some embodiments. The removal process includes a photolithography process and an etching process, in accordance with some embodiments.

As shown in FIG. 1P, conductive via structures 242 and 244 and a conductive line 246 are formed in the holes 232 and 234 and the trench 236 respectively, in accordance with some embodiments. In this step, a semiconductor device structure 100 is substantially formed, in accordance with some embodiments.

The conductive line 246 are connected between the conductive via structures 242 and 244, in accordance with some embodiments. The gate electrode 182 is electrically connected to the conductive plug 160 through the conductive via structure 242, the conductive line 246, the conductive via structure 244, and the dummy gate electrode 184, in accordance with some embodiments. The dummy gate electrode 184 is electrically connected between the conductive plug 160 and the gate electrode 182 of the gate stack G, in accordance with some embodiments.

Since the conductive plug 160 is made of a metal-containing material, the conductivity of the conductive plug 160 is high, and the charges in the gate electrode 182 of the gate stack G can be quickly grounded by the conductive plug 160. Therefore, the performance of the semiconductor device structure 100 is improved.

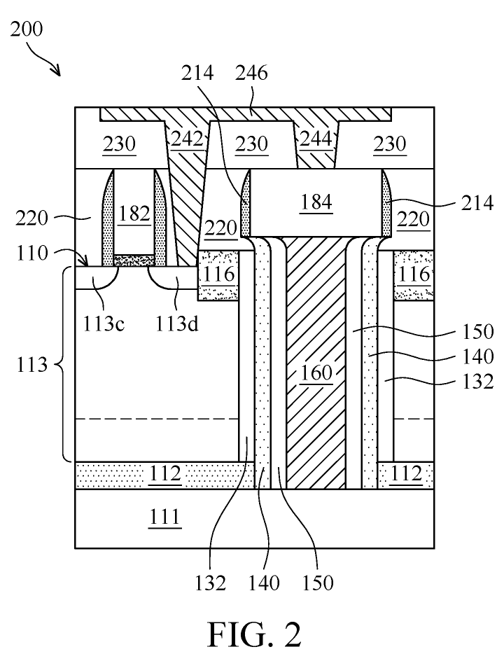

FIG. 2 is a cross-sectional view of a semiconductor device structure 200, in accordance with some embodiments. As shown in FIG. 2, the semiconductor device structure 200 is similar to the semiconductor device structure 100, except that the conductive via structure 242 of the semiconductor device structure 200 is electrically and physically connected to the source drain region 113d of the semiconductive layer 113, in accordance with some embodiments.

Therefore, the source drain region 113d is electrically connected to the conductive plug 160 through the conductive via structure 242, the conductive line 246, the conductive via structure 244, and the dummy gate electrode 184, in accordance with some embodiments. The dummy gate electrode 184 is electrically connected between the conductive plug 160 and the source drain region 113d, in accordance with some embodiments.

Since the conductive plug 160 is made of a metal-containing material, the conductivity of the conductive plug 160 is high, and the charges in the source drain region 113d can be quickly grounded by the conductive plug 160. Therefore, the performance of the semiconductor device structure 200 is improved.

Processes and materials for forming the semiconductor device structure 200 may be similar to, or the same as, those for forming the semiconductor device structure 100 described above. Elements designated by the same or similar reference numbers as those in FIGS. 1A - 2 have the same or similar structures and the materials. Therefore, the detailed descriptions thereof will not be repeated herein.

In accordance with some embodiments, semiconductor device structures and methods for forming the same are provided. The methods (for forming the semiconductor device structure) form a conductive plug in a SOI substrate. The conductive plug passes through a first semiconductive layer and an oxide layer and is connected to a second semiconductive layer, and is made of a metal-containing material. Since the conductive plug is made of the metal-containing material, the conductivity of the conductive plug is high, and the charges in device elements formed at the first semiconductive layer can be quickly grounded by the conductive plug. Therefore, the performance of the semiconductor device structure is improved.

In accordance with some embodiments, a method for forming a semiconductor device structure is provided. The method includes providing a substrate including a first semiconductive layer, a second semiconductive layer, an oxide layer, and an isolation structure. The oxide layer is between the first semiconductive layer and the second semiconductive layer, and the isolation structure is embedded in the second semiconductive layer. The method includes partially removing the isolation structure and the second semiconductive layer to form a hole passing through the isolation structure and the second semiconductive layer. The method includes forming a spacer layer over an inner wall of the hole. The method includes removing a portion of the oxide layer under the hole. The hole further passes through the oxide layer after the portion of the oxide layer is removed. The method includes forming a conductive plug in the hole. The conductive plug passes through the isolation structure, the second semiconductive layer, the spacer layer, and the oxide layer and is electrically connected to the first semiconductive layer, and the conductive plug includes a metal-containing material.

In accordance with some embodiments, a method for forming a semiconductor device structure is provided. The method includes providing a substrate including a first semiconductive layer, a second semiconductive layer, an oxide layer, and an isolation structure. The oxide layer is between the first semiconductive layer and the second semiconductive layer, and the isolation structure is embedded in the second semiconductive layer. The method includes partially removing the isolation structure, the second semiconductive layer, and the oxide layer to form a hole passing through the isolation structure, the second semiconductive layer, and the oxide layer. The method includes forming a first insulating layer over an inner wall of the hole. The method includes forming a conductive plug in the hole. The conductive plug passes through the isolation structure, the second semiconductive layer, the first insulating layer, and the oxide layer and is electrically connected to the first semiconductive layer, and the conductive plug includes a metal-containing material.

In accordance with some embodiments, a semiconductor device structure is provided. The semiconductor device structure includes a substrate including a first semiconductive layer, a second semiconductive layer, an oxide layer, and an isolation structure. The oxide layer is between the first semiconductive layer and the second semiconductive layer, the isolation structure is embedded in the second semiconductive layer and interfaces an end portion of an active region of the second semiconductive layer, and the isolation structure includes an oxide-based material. The semiconductor device structure includes a conductive plug passing through the isolation structure, the second semiconductive layer, and the oxide layer and electrically connected to the first semiconductive layer. The conductive plug includes a metal-containing material. The semiconductor device structure includes a spacer layer between the conductive plug and the second semiconductive layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
providing a substrate comprising a first semiconductive layer, a second semiconductive layer, an oxide layer, and an isolation structure, wherein the oxide layer is between the first semiconductive layer and the second semiconductive layer, and the isolation structure is embedded in the second semiconductive layer;
partially removing the isolation structure and the second semiconductive layer to form a hole passing through the isolation structure and the second semiconductive layer;
forming a spacer layer over an inner wall of the hole;
removing a portion of the oxide layer under the hole, wherein the hole further passes through the oxide layer after the portion of the oxide layer is removed; and
forming a conductive plug in the hole, wherein the conductive plug passes through the isolation structure, the second semiconductive layer, the spacer layer, and the oxide layer and is electrically connected to the first semiconductive layer, and the conductive plug comprises a metal-containing material.

2. The method for forming the semiconductor device structure as claimed in claim 1, further comprising:
forming a gate stack over the second semiconductive layer, wherein the gate stack comprises a gate dielectric layer and a gate electrode over the gate dielectric layer, and the gate electrode is electrically connected to the conductive plug.

3. The method for forming the semiconductor device structure as claimed in claim 2, further comprising:
forming a dummy gate electrode over the conductive plug, wherein the dummy gate electrode is electrically connected between the conductive plug and the gate electrode of the gate stack.

4. The method for forming the semiconductor device structure as claimed in claim 3, wherein the dummy gate electrode and the gate electrode of the gate stack are made of a same material.

5. The method for forming the semiconductor device structure as claimed in claim 3, wherein a bottom surface of the dummy gate electrode is substantially level with a top surface of the conductive plug.

6. The method for forming the semiconductor device structure as claimed in claim 1, further comprising:
forming a gate stack over the second semiconductive layer;
forming a gate spacer over sidewalls of the gate stack; and
forming a first source drain region and a second source drain region in the second semiconductive layer, wherein the gate stack is between the first source drain region and the second source drain region, and the first source drain region is electrically connected to the conductive plug.

7. The method for forming the semiconductor device structure as claimed in claim 6, further comprising:
forming a dummy gate electrode over the conductive plug, wherein the dummy gate electrode is electrically connected between the conductive plug and the first source drain region.

8. The method for forming the semiconductor device structure as claimed in claim 1, further comprising:
forming a first insulating layer over the inner wall of the hole after the portion of the oxide layer under the hole is removed and before the conductive plug is formed in the hole, wherein the first insulating layer is between the spacer layer and the conductive plug and between the oxide layer and the conductive plug.

9. The method for forming the semiconductor device structure as claimed in claim 8, further comprising:
forming a second insulating layer over the first insulating layer before the conductive plug is formed in the hole, wherein the second insulating layer is between the first insulating layer and the conductive plug.

10. The method for forming the semiconductor device structure as claimed in claim 9, wherein a first dielectric constant of the first insulating layer is greater than a second dielectric constant of the second insulating layer.

11. A method for forming a semiconductor device structure, comprising:
providing a substrate comprising a first semiconductive layer, a second semiconductive layer, an oxide layer, and an isolation structure, wherein the oxide layer is between the first semiconductive layer and the second semiconductive layer, and the isolation structure is embedded in the second semiconductive layer;
partially removing the isolation structure, the second semiconductive layer, and the oxide layer to form a hole passing through the isolation structure, the second semiconductive layer, and the oxide layer;
forming a first insulating layer over an inner wall of the hole; and
forming a conductive plug in the hole, wherein the conductive plug passes through the isolation structure, the second semiconductive layer, the first insulating layer, and the oxide layer and is electrically connected to the first semiconductive layer, and the conductive plug comprises a metal-containing material.

12. The method for forming the semiconductor device structure as claimed in claim 11, wherein the first insulating layer is made of a metal oxide material.

13. The method for forming the semiconductor device structure as claimed in claim 11, further comprising:
forming a second insulating layer over the first insulating layer before the conductive plug is formed in the hole, wherein the second insulating layer is between the first insulating layer and the conductive plug.

14. The method for forming the semiconductor device structure as claimed in claim 11, wherein a first top surface of the conductive plug is higher than a second top surface of the isolation structure.

15. The method for forming the semiconductor device structure as claimed in claim 14, wherein a third top surface of the first insulating layer is higher than the second top surface of the isolation structure.

16. A semiconductor device structure, comprising:
a substrate comprising a first semiconductive layer, a second semiconductive layer, an oxide layer, and an isolation structure, wherein the oxide layer is between the first semiconductive layer and the second semiconductive layer, the isolation structure is embedded in the second semiconductive layer and interfaces an end portion of an active region of the second semiconductive layer, and the isolation structure comprises an oxide-based material;
a conductive plug passing through the isolation structure, the second semiconductive layer, and the oxide layer and electrically connected to the first semiconductive layer, wherein the conductive plug comprises a metal-containing material; and
a spacer layer between the conductive plug and the second semiconductive layer.

17. The semiconductor device structure as claimed in claim 16, further comprising:
a gate stack over the second semiconductive layer, wherein the gate stack comprises a gate dielectric layer and a gate electrode over the gate dielectric layer, and the gate electrode is electrically connected to the conductive plug.

18. The semiconductor device structure as claimed in claim 17, further comprising:
a dummy gate electrode over the conductive plug, wherein the dummy gate electrode is electrically connected between the conductive plug and the gate electrode of the gate stack.

19. The semiconductor device structure as claimed in claim 16, further comprising:
a first insulating layer between the spacer layer and the conductive plug and between the oxide layer and the conductive plug.

20. The semiconductor device structure as claimed in claim 19, further comprising:
a second insulating layer between the first insulating layer and the conductive plug.
